(19) United States
(12) Patent Application Publication
(10) Pub. No.: US 2026/0123490 A1
(43) Pub. Date: Apr. 30, 2026

(54) MEMORY MODULES WITH GLASS SUBSTRATES

(71) Applicant: Micron Technology, Inc., Boise, ID (US)

(72) Inventors: Chan H. Yoo, Boise, ID (US); Walter L. Moden, Boise, ID (US); Christopher D. Glancey, Boise, ID (US); Tracy N. Tennant, Boise, ID (US); Stephen F. Moxham, Boise, ID (US)

(21) Appl. No.: 19/361,899

(22) Filed: Oct. 17, 2025

Related U.S. Application Data
(60) Provisional application No. 63/711,610, filed on Oct. 24, 2024.

(51) Int. Cl. H01L 23/498; H01L 21/48; H01L 21/56; H01L 23/00; H01L 23/15; H01L 23/31; H01L 23/538; H01L 25/18; H10B 80/00; H10D 80/30

(52) U.S. Cl. CPC H10W 70/685; H10W 70/05; H10W 70/095; H10W 70/611; H10W 70/69; H10W 70/692; H10W 74/014; H10W 74/114; H10B 80/00; H10D 80/30; H10W 72/0198; H10W 90/00; H10W 90/724

(57) ABSTRACT

Methods, systems, and devices for memory modules with glass substrates are described. A glass substrate may be implemented in various memory devices. For example, a glass substrate may be formed. One or more redistribution layers (RDLs) may be formed by depositing layers of materials onto one or more surfaces of the glass substrate. Memory dies may be bonded onto a surface of the RDLs. Singulation operations may be performed to separate operable memory dies into memory chips, such that each memory chip may include a portion of the glass substrate, a portions of the RDLs, and one or more memory dies.

### CROSS REFERENCE

The present Application for Patent claims priority to U.S. Patent Application No. 63/711,610 by Yoo et al., entitled “MEMORY MODULES WITH GLASS SUBSTRATES,” filed Oct. 24, 2024, which is assigned to the assignee hereof, and which is expressly incorporated by reference in its entirety herein.

### TECHNICAL FIELD

The following relates to one or more systems for memory, including memory modules with glass substrates.

### BACKGROUND

Memory devices are used to store information in devices such as computers, user devices, wireless communication devices, cameras, digital displays, and others. A memory device may be manufactured on a substrate or base wafer and information may be stored to the memory device(s) by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that support memory modules with glass substrates in accordance with examples as disclosed herein.

FIGS. 2A, 2B, 2C, 2D, and 2E show examples of layouts that support memory modules with glass substrates in accordance with examples as disclosed herein.

FIG. 3 shows an example of a memory architecture that supports memory modules with glass substrates in accordance with examples as disclosed herein.

FIG. 4 shows a flowchart illustrating a method or methods that support memory modules with glass substrates in accordance with examples as disclosed herein.

### DETAILED DESCRIPTION

Some memory devices may be manufactured by depositing onto, and coupling various components with, a substrate or base wafer. For example, some memory devices may include a printed circuit board (PCB) that other materials are deposited onto (e.g., deposited above). A PCB may be manufactured by forming layers of various materials on top of each other until a substrate or a base wafer is formed. However, some techniques utilized in building the PCBs may be outdated or may otherwise be undesirable. That is, PCB build up technology may be limited to large line (e.g., space) capabilities of conducting layers. That is, current PCBs may include a relatively large quantity of conducting layers, resulting in a relatively large structure.

Additionally, PCBs may be associated with a relatively low reliability performance level due to mismatches in coefficients of thermal expansion (CTEs) (and/or other characteristics) associated with various components on and conductive aspects of the PCB, which may attempt to be addressed using expensive and complicated underfill processes. Additionally, or alternatively, some PCBs may be associated with poor heat dissipation. The space restrictions, reliability concerns, and poor thermal characteristics of PCBs may lead to similar problems in associated memory devices, which may result in high costs associated with manufacturing, larger quantities of physical space requirements, and unreliable memory systems. Thus, a memory module formed on a surface other than a PCB may be desirable.

To decrease use of physical space, increase reliability, and increase thermal efficiency of memory devices, a glass substrate may be implemented in various memory devices. For example, a glass substrate may be formed and one or more redistribution layers (RDLs) may be formed by depositing layers of materials onto and/or above one or more surfaces of the glass substrate. Memory components may be surface mounted to the RDLs and various tests may be performed to determine the operability of the memory module. Singulation operations may be performed to separate operable memory modules. Because the glass substrate may include fine line (e.g., space) conductors that may reduce a quantity of layers in the substrate of each memory device, signal routing within the memory device, high speed signal shielding, and power delivery efficiency from a host system to the memory components of the memory module may be increased. Additionally, glass substrates may decrease CTE mismatch and thus increase reliability, as the board mounting and bonding process may be simplified (e.g., relative to a PCB). In some examples, a glass substrate may also be physically thinner than a PCB substrate, which may allow better airflow between memory components of the memory module and promote increased heat dissipation, among other benefits.

In addition to applicability in memory systems as described herein, techniques for memory modules with glass substrates may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

In addition to applicability in memory systems and various electronic devices as described herein, techniques for memory modules with glass substrates may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices and eliminating production processes, which may result in lowered production emissions, reduce electronic waste, and extend the life of electronic devices and thereby reducing electronic waste, among other benefits.

Features of the disclosure are illustrated and described in the context of systems and architectures. Features of the disclosure are further illustrated and described in the context of layouts and memory architectures and flowcharts.

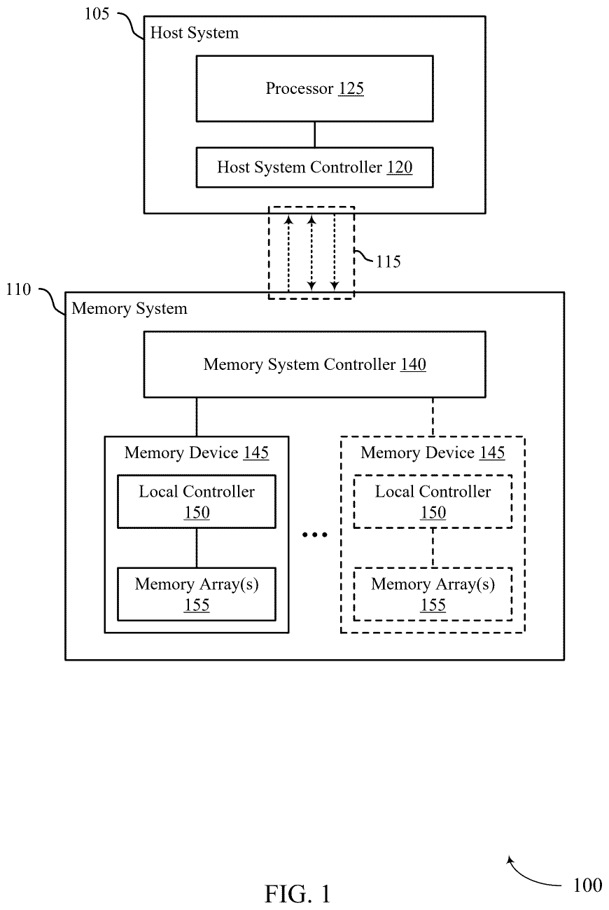

FIG. 1 illustrates an example of a system 100 that supports memory modules with glass substrates in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, the memory devices 145 may be manufactured by depositing onto, and coupling various components with, a substrate or base wafer. For example, some memory devices may include a PCB that other materials are deposited onto (e.g., above). A PCB may be manufactured by forming layers of various materials on top of each other until a substrate or base wafer is formed. However, some techniques utilized in building the PCBs may be outdated or may otherwise be undesirable. That is, PCB build up technology may be limited to large line (e.g., space) capabilities of conducting layers. Additionally, PCBs may be associated with a relatively low reliability performance level due to mismatches in CTEs associated with various components on and conductive aspects of the PCB, which may be addressed using expensive underfill processes. Additionally, or Alternatively, some PCBs may be associated with poor heat dissipation. The space restrictions, reliability concerns, and poor thermal characteristics of PCBs may lead to similar problems in associated memory devices, which may result in high costs associated with manufacturing, larger quantities of physical space requirements, and unreliable memory systems. Thus, a memory module formed on a surface other than a PCB may be desirable.

To decrease use of physical space, increase reliability, and increase thermal efficiency of the memory devices 145, a glass substrate may be implemented in the memory devices 145. For example, a glass substrate may be formed and one or more RDLs may be formed by depositing layers of materials onto one or more surfaces of the glass substrate. Memory components may be surface mounted to the RDLs and various tests may be performed to determine the operability of the memory module. Singulation operations may be performed to separate operable memory modules. Because the glass substrate may include fine line (e.g., space) conductors that may reduce a quantity of layers in the substrate of each memory device 145, signal routing within the memory device, high speed signal shielding, and power delivery from a host system to the memory components of the memory module may be increased. Additionally, glass substrates may decrease CTE mismatch and thus increase reliability, as the board mounting and bonding process may be simplified (e.g., relative to a PCB) when using a glass substrate. In some examples, a glass substrate may also be physically thinner than a PCB substrate, which may allow better airflow between memory components of the memory module and promote increased heat dissipation.

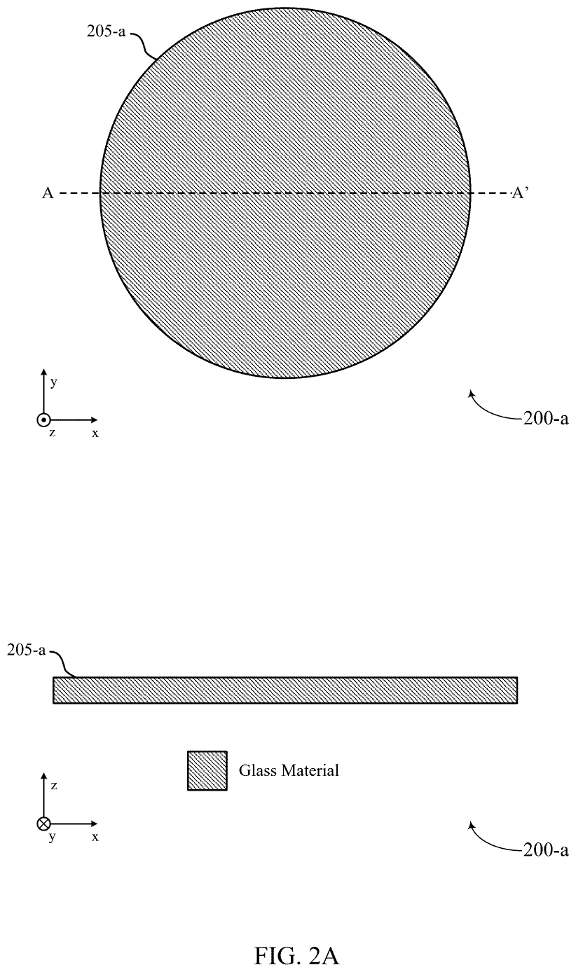

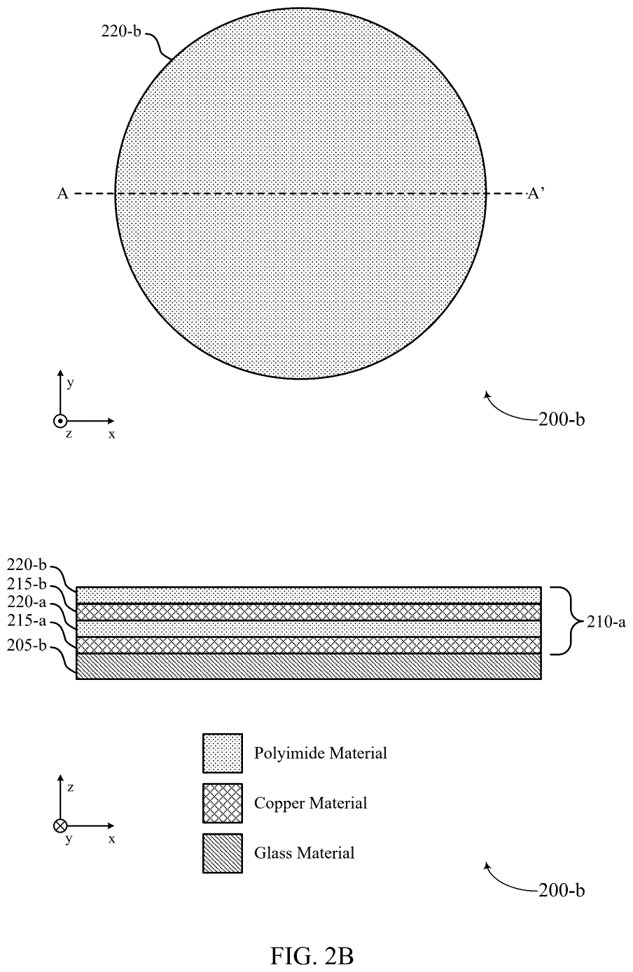

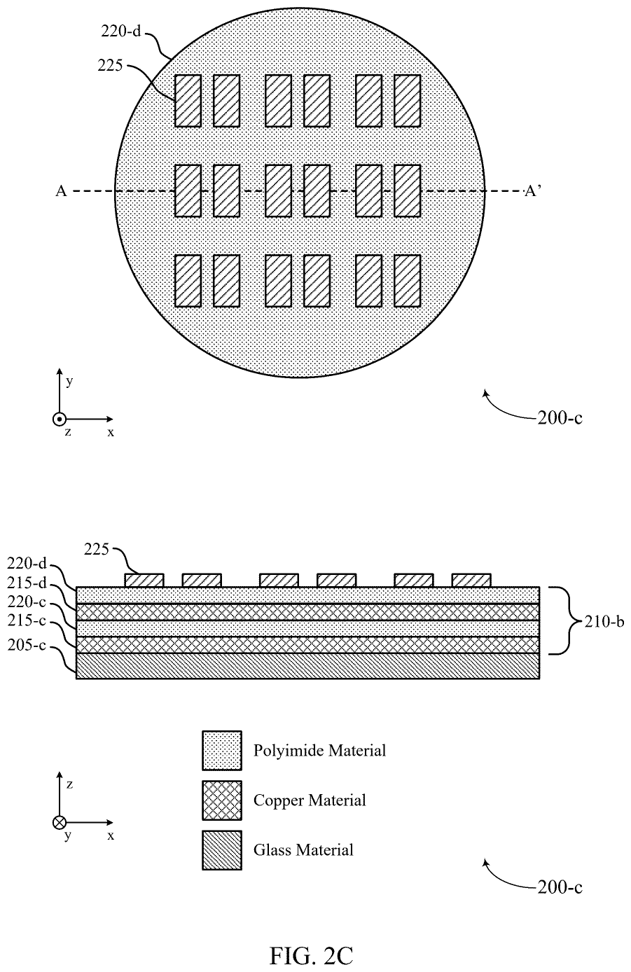

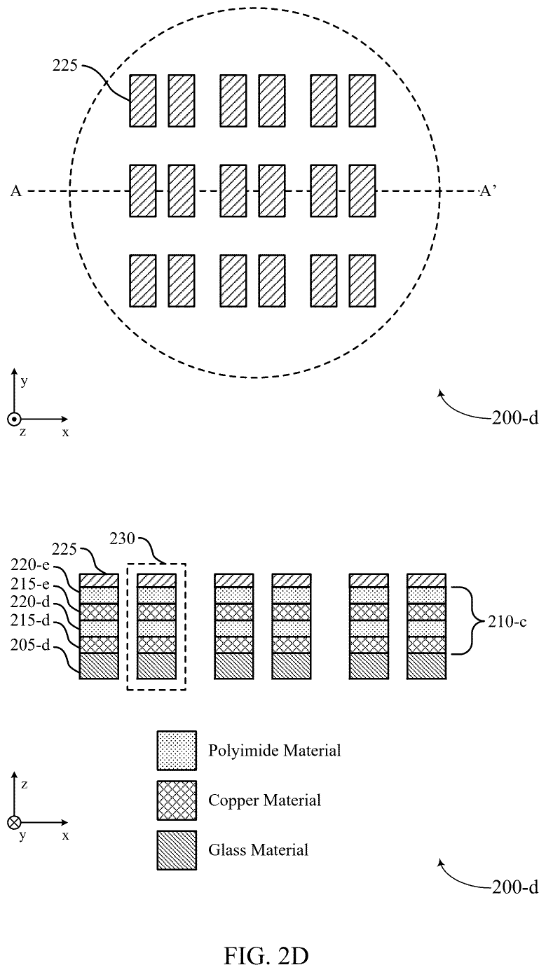

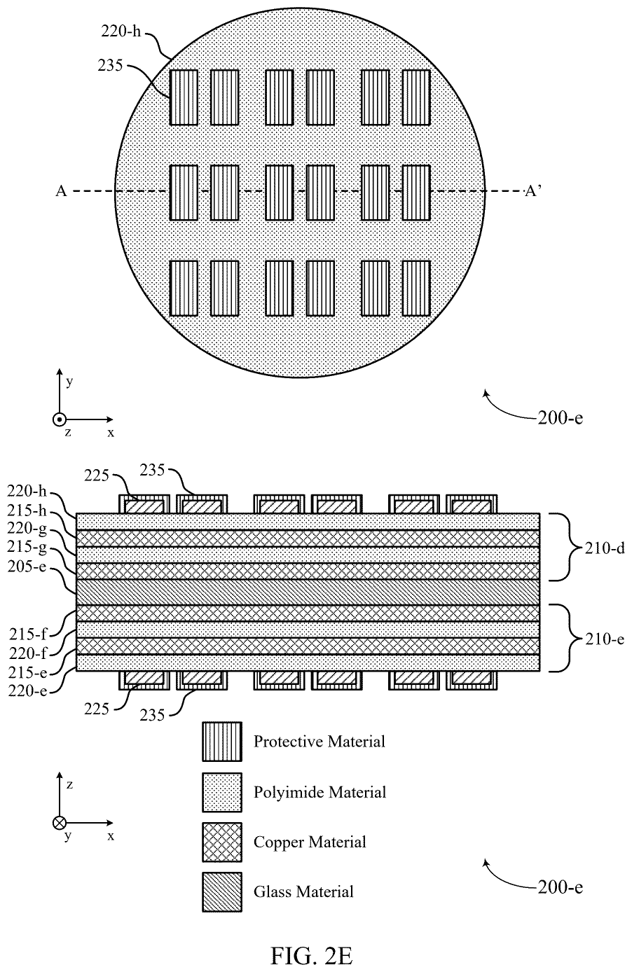

FIGS. 2A through 2E illustrate examples of operations that support memory modules with glass substrates in accordance with examples as disclosed herein. For example, FIGS. 2A through 2E may illustrate aspects of a sequence of manufacturing operations for fabricating aspects of a layout 200, which may be a portion of a memory device (e.g., a portion of a memory device 145). Each view of the FIGS. 2A through 2E may be described with reference to an x-direction, a y-direction, and a z-direction, as illustrated. The manufacturing operations illustrate various views of the layout 200. For example, the manufacturing operations illustrate top views of the layout 200 (e.g., top down views in the −z direction) and cross-sectional views of the layout 200 in an xz-plane along the A-A′ cross-section through the layout 200. Although the layout 200 illustrates examples of certain relative dimensions and quantities of various features, aspects of the layout 200 may be implemented with other relative dimensions or quantities of such features in accordance with examples as disclosed herein.

Operations illustrated in and described with reference to FIGS. 2A through 2E may be performed by a manufacturing system, such as a semiconductor fabrication system configured to perform additive operations such as deposition or bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 2A illustrates a portion of a layout 200-a after a manufacturing step (e.g., a first manufacturing step). The manufacturing step may include forming (e.g., providing, depositing) a glass substrate 205-a. The glass substrate 205-a may be an example of a glass wafer over which various layers are formed (e.g., deposited). The glass substrate 205-a may include glass material. For example, the glass substrate 205-a may be formed by depositing a single layer of the glass material. In some examples, the glass substrate 205-a may include fine line (e.g., space) conductors. The fine line conductors may reduce a quantity of layers in the glass substrate 205-a, as well as signal routing within the glass substrate 205-a, high speed signal shielding associated with the glass substrate 205-a, and power delivery from an associated host system to the glass substrate 205-a (e.g., components associated or coupled with the glass substrate 205-a). For example, the fine line conductors may be an example of one or more traces or communication lines associated with communications (e.g., signaling) between components associated with the glass substrate 205-a or components external to (e.g., coupled with) the glass substrate 205-a. Additionally, the glass substrate 205-a may decrease CTE mismatch and thus increase reliability. For example, various board mounting and bonding processes may be simplified by utilizing the glass substrate 205-a. In some examples, the glass substrate 205-a may also be physically thinner than a PCB substrate, which may allow better airflow between memory components of the memory module and promote increased heat dissipation. For example, the glass substrate 205-a may be an order of magnitude thinner (e.g., four times thinner) than a PCB substrate.

FIG. 2B illustrates a portion of a layout 200-b after a manufacturing step (e.g., a second manufacturing step). The second set of manufacturing operations may include forming (e.g., forming, depositing) a redistribution layer 210-a on a top surface (e.g., in the z-direction) of the glass substrate 205-b. For example, the manufacturing step may include depositing layers of conducting materials and patternable dielectric materials (e.g., a copper material, a polyimide material, a silicon oxide material, a silicon nitride material, a polybenzoxazole material, respectively) to form the redistribution layer 210-a. The manufacturing step may be examples of wafer-level or panel-level build up processes. After completion of the manufacturing step, the redistribution layer 210-a may include one or more alternating copper layers 215, polyimide layers 220, and other layers (e.g., not illustrated) in an xy-plane and stacked on top of each other in the z-direction. For example, the redistribution layer 210-a may include a copper layer 215-a formed over the top surface (e.g., in the z-direction) of the glass substrate 205-b, a polyimide layer 220-a formed over a top surface of the copper layer 215-a, a copper layer 215-b formed over a top surface of the polyimide layer 220-a, and a polyimide layer 220-b formed over a top surface of the copper layer 215-b. The manufacturing step may result in the redistribution layer 210-a.

The manufacturing step may include forming through-glass vias (TGVs) through one or more layers of the redistribution layer 210-a. Each of the TGVs may couple (e.g., connect) one or more layers of the redistribution layer 210-a. In some examples, the TGVs may also couple one or more layers of the redistribution layer 210-a to one or more components on a top surface of the redistribution layer 210-a (e.g., on a top surface of the polyimide layer 220-b). In some examples, the manufacturing step may also include performing one or more etching processes on one or more of the layers of the redistribution layer 210-a. For example, the manufacturing step may also include forming conductive paths at the copper layers 215 of the redistribution layer 210-a, coupling the copper layers 215 with other layers or components, or a combination thereof. After the manufacturing step, one or more of the copper layers 215 may include one or more metal traces (e.g., not illustrated). Each of the copper layers 215 may include one or more interconnects that may communicate (e.g., route) various signaling, such as input/output (I/O) signaling, to different parts of the associated memory device. For example, the copper layers 215 may include one or more traces or communication lines associated with communications between components coupled with the glass substrate 205-a. The copper layers 215 may facilitate signaling between the glass substrate 205-a and one or more memory dies coupled with the redistribution layer 210-a. In some instances, the redistribution layer 210-a may be relatively thin compared to conventional redistribution layers, which may result in a relatively smaller (e.g., thinner) memory device or memory module. For example, mounting memory components to the redistribution layer 210-a via flip-chip interconnects (e.g., copper pillars) may result in a thinner memory device relative to using a traditional substrate and solder balls to connect the memory components to the redistribution layer 210-a.

FIG. 2C illustrates a portion of a layout 200-c after a manufacturing step (e.g., a third manufacturing step). The manufacturing step may include bonding memory dies 225 to a top surface of the redistribution layer 210-b (e.g., a top surface of a polyimide layer 220-d) in the z-direction. In some examples, the manufacturing step may include bonding the plurality of memory dies 225 to the redistribution layer 210-b using a flip-chip interconnect, one or more bumps, or another technique (e.g., not illustrated).

The manufacturing step may include bonding the memory dies 225 to the redistribution layer 210-b using one or more bumps. For example, to bond the memory dies 225 to the redistribution layer 210-b using bumps (e.g., corresponding pillar or solder or metal pads or balls), one or more bumps may be formed on a top surface of the redistribution layer 210-b. One or memory dies 225 may be bonded to a top surface of the bumps such that the bumps may connect (e.g., couple) the memory dies 225 to the surface of the redistribution layer 210-b (e.g., not illustrated). One or more heating processes may be performed to connect the memory dies 225 to the bumps.

The manufacturing step may include bonding the memory dies 225 to the redistribution layer 210-b using a flip-chip interconnect. To bond the memory dies 225 to the redistribution layer 210-b using a flip-chip interconnect, bumps may first be formed on a surface of the memory dies 225. For example, solder bumps may be deposited on a top surface of each of the memory dies 225 and heated such that the bumps bond to the memory dies 225. The memory dies 225 may then be flipped over such that the top surface of the memory dies 225 (e.g., and the solder bumps) is face down. One or more heating processes may be performed to complete the bonding process. In some examples, the memory dies 225 may be bonded to a surface of the glass substrate 205-c (e.g., rather than to a surface of the redistribution layer 210-b). For example, the manufacturing step may include directly (e.g., or in a hybrid manner) bonding the memory dies 225 to one or more contacts on a surface of the glass substrate 205-c. In one example, the memory dies 225 may be bonded to the glass substrate 205-c using a chip-to-wafer (CoW) technique.

In some examples, the manufacturing step may include performing one or more testing operations on the memory dies 225. For example, based on bonding the memory dies 225 to the redistribution layer 210-b, one or more burn-in or stress-test operations may be performed on the memory dies 225 of the layout 200-c to determine whether each memory die 225 may be associated with an error. In some examples, an error may be an example of a physical defect that may result in one or more electrical defects or imperfections. For example, a test operation may detect a physical defect that may result in an incorrect quantity of bits or in one or more unexpected bits relative to a test quantity of bits or a test bit sequence. In some other examples, the error may be associated with operating the associated memory chip (e.g., memory device). For example, the test operation may detect an error associated with operating the memory die 225.

In some examples, the manufacturing step may include depositing a protective material (e.g., a protective covering) over each of the memory dies 225 (e.g., as further described with reference to FIG. 2E). In some examples, the protective material may be deposited over and around each of the memory dies 225 in the z-direction and within the xy-plane. The protective material may separate a top surface of each of the memory dies 225 in the z-direction, and side surfaces of the memory dies 225 along the x-direction and may protect the memory dies 225 from being damaged (e.g., by an external force).

FIG. 2D illustrates a portion of a layout 200-d after a manufacturing step (e.g., a fourth manufacturing step). The manufacturing step may include singulating the memory dies 225 and other components previously mounted to a surface of the redistribution layer 210-c (not illustrated) to form memory modules 230. After bonding memory dies 225 to the top surface of the redistribution layer 210-c, one or more operations (e.g., one or more dicing operations, one or more operations to separate the wafer into one or more modules) may be performed to separate the memory dies 225 and associated portions of the redistribution layer 210-c and the glass substrate 205-d from other memory dies 225. For example, after performing the one or more singulation operations, the one or more memory modules 230 may be formed. In some examples, each of the memory modules 230 may include a single pillar structure of one of the memory dies 225, one or more additional memory components (e.g., packages, not illustrated), a portion of the redistribution layer 210-c (e.g., a portion of the copper layer 215-d, a portion of the polyimide layer 220-d, a portion of the copper layer 215-e, a portion of the polyimide layer 220-e), and a portion of the glass substrate 205-d. In other examples, each memory module 230 may include multiple pillar structures (e.g., multiple memory dies 225 and associated layers).

Each of the memory modules 230 may also include one or more components associated with a power management integrated circuit (PMIC), one or more controllers, or other components. For example, a memory module 230 may include one or more PMIC components or controllers on a top surface of the memory modules 230 and at a same layer as the memory dies 225 (e.g., on a top surface of the redistribution layer 210-c). Each of the PMIC components and controllers may be coupled with various other components of the associated memory module 230 via one or more vias throughout the memory module 230. In some examples, each of the memory modules 230 may include one or more GTVs that may connect the one or more memory dies 225 to one or more of the layers of the redistribution layer 210-c. Each of the memory modules 230 may include an example of a volatile memory device, a non-volatile memory device, or may otherwise include another memory type. For example, each of the memory modules 230 may include one or more of the memory dies 225, which may each include DRAM. One or more of the memory modules 230 may be an example of a dual in-line memory module (DIMM), a compression attach memory module (CAMM), an SSD, or another memory module type. Each memory module 230 may include one or more DRAM (e.g., RAM) memories on a substrate, and may include pins that couple the DIMM to a larger circuit or memory system. In some examples, each DIMM may store each data bit in a separate memory cell.

DIMM is a module that contains one or several random access memory (RAM) chips on a small circuit board with pins that connect it to the computer motherboard. The DIMM stores each data bit in a separate memory cell.

In some examples, the manufacturing step may include performing one or more memory chip testing operations to determine whether each of the memory modules 230 may be operable. For example, a test operation may be performed on each of the memory modules 230 and one or more of the memory modules 230 that test to be inoperable may be discarded, while one or more of the memory modules 230 that test to be operable may be retained. In some examples, an error may be an example of a physical defect that may result in one or more electrical inaccuracies. For example, a test operation may detect a physical defect that may result in an incorrect quantity of bits or in one or more unexpected bits relative to a test quantity of bits or a test bit sequence. In some other examples, the error may be associated with operating the associated memory module 230 (e.g., or the associated memory device). For example, the test operation may detect an error associated with operating a memory die 225 of one of the memory modules 230.

FIG. 2E illustrates a portion of a layout 200-e after an alternative manufacturing step. The alternative manufacturing step may include forming (e.g., laying, depositing) another redistribution layer 210-e on a bottom surface (e.g., in the z-direction) of the glass substrate 205-e. For example, the alternative set of manufacturing operations may include depositing one or more additional layers of a copper material and a polyimide material to form the redistribution layer 210-e, such that the layout 200-e may include a redistribution layer 210-d on a top surface of the glass substrate 205-e and the redistribution layer 210-e on a bottom surface of the glass substrate 205-e. In some examples, the redistribution layer 210-e may be formed and the memory dies 225 bonded to a surface of the redistribution layer 210-e after the redistribution layer 210-d has been formed and the memory dies 225 bonded to a surface of the redistribution layer 210-d.

After completion of the alternative set of manufacturing operations, the redistribution layer 210-a may include one or more alternating copper layers 215, polyimide layers 220, and other layers (e.g., not illustrated) in an xy-plane and stacked over each other in the z-direction (e.g., as further described herein). For example, the redistribution layer 210-d may include a copper layer 215-g formed over the top surface (e.g., in the z-direction) of the glass substrate 205-e, a polyimide layer 220-g formed over a top surface of the copper layer 215-g, a copper layer 215-h formed over a top surface of the polyimide layer 220-g, and a polyimide layer 220-h formed over a top surface of the copper layer 215-h. Additionally, the redistribution layer 210-e may include a copper layer 215-f formed under the bottom surface (e.g., in the z-direction) of the glass substrate 205-e, a polyimide layer 220-f formed under a bottom surface of the copper layer 215-f, a copper layer 215-e formed under a bottom surface of the polyimide layer 220-f, and a polyimide layer 220-e formed under a bottom surface of the copper layer 215-e.

The alternative set of manufacturing operations may include forming TGVs through one or more layers of the redistribution layer 210-d and one or more layers of the redistribution layer 210-e. Each of the TGVs may couple (e.g., connect) one or more layers of the redistribution layers 210. In some examples, the TGVs may also couple one or more layers of each of the redistribution layers 210 to one or more components on a top surface of the respective redistribution layer 210 (e.g., on a top surface of the polyimide layer 220-h, on a bottom surface of the polyimide layer 220-e). In some examples, the manufacturing step may also include performing one or more etching processes on one or more of the layers of the redistribution layers 210 (e.g., as further described herein).

The alternative set of manufacturing operations may include bonding memory dies 225 to a top surface of the redistribution layer 210-d (e.g., a top surface of a polyimide layer 220-h) and to a bottom surface of the redistribution layer 210-e (e.g., a top surface of a polyimide layer 220-e) in the z-direction. In some examples, the memory dies 225 may be bonded to the redistribution layer 210-d prior to being bonded to the redistribution layer 210-e. The memory dies 225 may be bonded and tested as described further herein with reference to FIG. 2C. In some examples, the alternative set of manufacturing operations may also include depositing a protective covering 235 over each of the memory dies 225, as further described herein. For example, after performing the alternative set of manufacturing operations, a protective covering 235 may encapsulate (e.g., cover, surround) each of the memory dies 225 bonded to one or both of the redistribution layers 210.

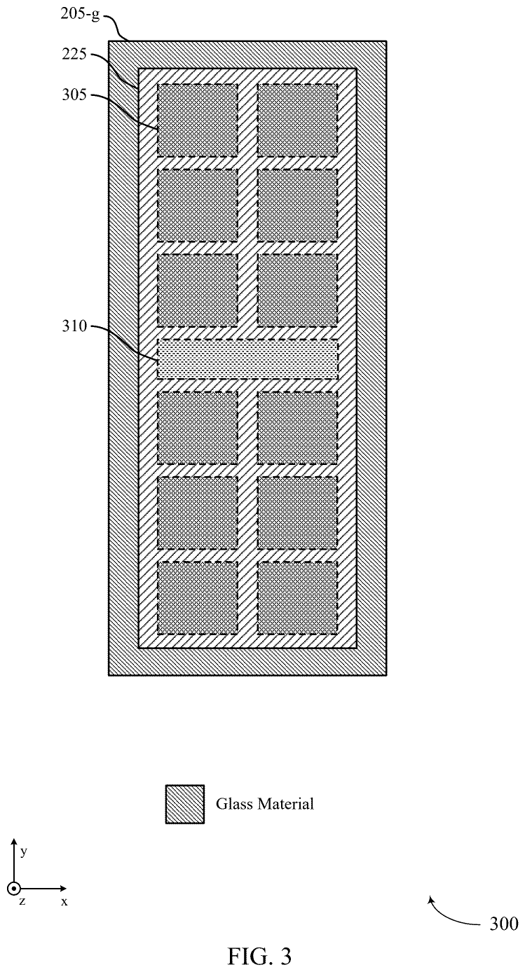

FIG. 3 shows an example of a memory architecture 300 that supports memory modules with glass substrates in accordance with examples as disclosed herein. The memory architecture 300 may be an example of a memory module 230 as described with reference to FIGS. 1 and 2D, respectively.

Some memory devices may be manufactured by depositing onto, and coupling various components with, a substrate or base wafer. For example, some memory devices may include a PCB that other materials are deposited onto (e.g., above). A PCB may be manufactured by forming layers of various materials on top of each other until a substrate or base wafer is formed. However, some techniques utilized in building the PCBs may be outdated or may otherwise be undesirable. That is, PCB build up technology may be limited to large line (e.g., space) capabilities of conducting layers. Additionally, PCBs may be associated with a relatively low reliability performance level due to mismatches in CTEs associated with various components on and conductive aspects of the PCB, which may be fixed using expensive underfill processes. Additionally, or Alternatively, some PCBs may be associated with poor heat dissipation. The space restrictions, reliability concerns, and poor thermal characteristics of PCBs may lead to similar problems in associated memory devices, which may result in high costs associated with manufacturing, larger quantities of physical space requirements, and unreliable memory systems. Thus, a memory module formed on a surface other than a PCB may be desirable.

To decrease use of physical space, increase reliability, and increase thermal efficiency of memory devices, a glass substrate 205 may be implemented. For example, a glass substrate 205 may be formed and one or more RDLs may be formed by depositing layers of materials onto one or more surfaces of the glass substrate 205 (e.g., not illustrated). Memory dies 225 may be bonded onto a surface of the RDLs and various tests may be performed to determine the operability of the bonded memory dies 225. In some implementations, at least 4, 8, 12, or 16 dies (or more) memory dies 225 may be bonded onto a surface of the RDLs.

Singulation operations may be performed to separate one or more operable memory dies 225 into memory chips (e.g., as depicted by the memory architecture 300) such that each chip may include a portion of the glass substrate 205, a portions of the RDLs, and other components as further described herein.

The memory architecture 300 may be an example of a single memory chip after performing a set of one or more manufacturing operations (e.g., as further described herein). The memory chip may include a glass substrate 205-g, a portion of one or more RDLs deposited on the top and bottom (e.g., in the z-direction) of the glass substrate 205-g (e.g., not illustrated), and one or more memory dies 225 bonded to a top surface of each RDL. For example, the memory architecture 300 may depict a single memory die 225 bonded to a top surface of an RDL that is deposited over a top surface of the glass substrate 205-g (e.g., in the z-direction). In some examples, the memory die 225 may include one or more volatile memory arrays 305 (e.g., DRAM) and a registered clock driver (RCD) 310, as well as various controllers and components associated with various interfaces (e.g., a PMIC). In some examples, the memory die 225 may be covered by a protective covering (e.g., not illustrated). The memory architecture 300 may be an example of a DIMM, as further described with reference to FIG. 2D.

Use of the glass substrate 205-g in the memory architecture 300 may result in increased efficiency and reliability of associated memory devices. For example, the glass substrate 205-g may include fine line (e.g., space) conductors, which may reduce a quantity of layers in the glass substrate 205-g. Such fine line capabilities of the glass substrate 205-g may increase signal routing within the memory architecture 300 and to other external components, high speed signal shielding, and power delivery from one or more external systems to the memory architecture 300, as further described herein. Additionally, the glass substrate 205-g may decrease CTE mismatch and increase reliability, as the board mounting and bonding process may be simplified with the glass substrate 205-g. In some examples, a glass substrate may also be physically thinner than a PCB substrate, which may allow better airflow between memory components (e.g., the volatile memory arrays 305, the RCD 310) of the memory architecture 300 and promote increased heat dissipation.

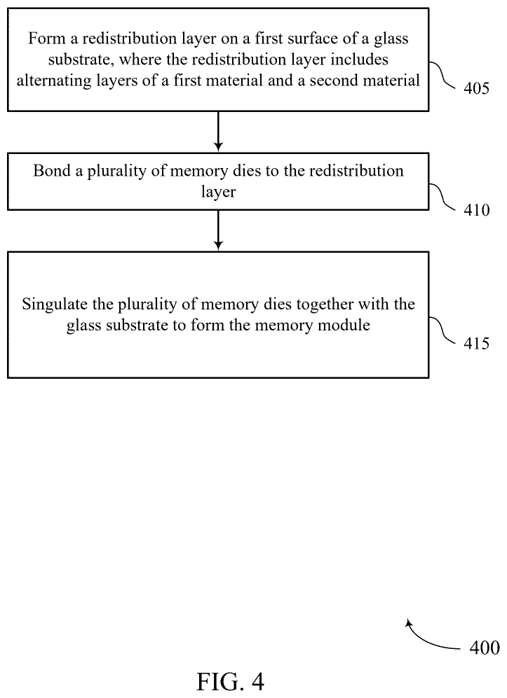

FIG. 4 shows a flowchart illustrating a method 400 that supports memory modules with glass substrates in accordance with examples as disclosed herein. The operations of method 400 may be implemented by a manufacturing system or its components as described herein. For example, the operations of method 400 may be performed by a manufacturing system as described with reference to FIGS. 1 through 3. In some examples, a manufacturing system may execute a set of instructions to control the functional elements of the device to perform the described functions. Additionally, or alternatively, the manufacturing system may perform aspects of the described functions using special-purpose hardware.

At 405, the method may include forming a redistribution layer on a first surface of a glass substrate, where the redistribution layer includes alternating layers of a first material and a second material. In some examples, aspects of the operations of 405 may be performed in accordance with examples as disclosed herein.

At 410, the method may include bonding a plurality of memory dies to the redistribution layer. In some examples, aspects of the operations of 410 may be performed in accordance with examples as disclosed herein.

At 415, the method may include singulating the plurality of memory dies to form a plurality of memory chips together with the glass substrate to form the memory module. In some examples, aspects of the operations of 415 may be performed in accordance with examples as disclosed herein.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for forming a redistribution layer on a first surface of a glass substrate, where the redistribution layer includes alternating layers of a first material and a second material; bonding a plurality of memory dies to the redistribution layer; and singulating the plurality of memory dies together with the glass substrate to form the memory module.
Aspect 2: The method, apparatus, or non-transitory computer-readable medium of aspect 1, further including operations, features, circuitry, logic, means, or instructions, or any combination thereof for prior to singulating, forming a second redistribution layer on a second surface of the glass substrate, where the second redistribution layer includes alternating layers of the first material and the second material; and bonding a second plurality of memory dies to the second redistribution layer, where singulating the plurality of memory dies together with the glass substrate also includes the second plurality of memory dies.
Aspect 3: The method, apparatus, or non-transitory computer-readable medium of aspect 2, where singulating the plurality of memory dies and singulating the second plurality of memory dies occur during a same manufacturing process.
Aspect 4: The method, apparatus, or non-transitory computer-readable medium of any of aspects 1 through 3, where bonding the plurality of memory dies to the redistribution layer includes operations, features, circuitry, logic, means, or instructions, or any combination thereof for bonding each of the plurality of memory dies to the redistribution layer using a flip-chip interconnect.
Aspect 5: The method, apparatus, or non-transitory computer-readable medium of any of aspects 1 through 4, where bonding the plurality of memory dies to the redistribution layer includes operations, features, circuitry, logic, means, or instructions, or any combination thereof for bonding each of the plurality of memory dies to the redistribution layer using a plurality of bumps.
Aspect 6: The method, apparatus, or non-transitory computer-readable medium of any of aspects 1 through 5, further including operations, features, circuitry, logic, means, or instructions, or any combination thereof for forming a protective covering around each of the plurality of memory dies bonded to the redistribution layer.
Aspect 7: The method, apparatus, or non-transitory computer-readable medium of any of aspects 1 through 6, where forming the redistribution layer includes operations, features, circuitry, logic, means, or instructions, or any combination thereof for depositing the alternating layers of the first material and the second material and forming respective conductive paths at the layers of the second material, where the one or more memory dies of a respective memory chip is coupled with the glass substrate via the respective conductive paths.
Aspect 8: The method, apparatus, or non-transitory computer-readable medium of any of aspects 1 through 7, further including operations, features, circuitry, logic, means, or instructions, or any combination thereof for forming one or more through glass vias in the redistribution layer, where the alternating layers of the first material and the second material are connected using the one or more through glass vias.
Aspect 9: The method, apparatus, or non-transitory computer-readable medium of any of aspects 1 through 8, where the first material includes a polyimide material and the second material includes copper.
Aspect 10: The method, apparatus, or non-transitory computer-readable medium of any of aspects 1 through 9, further including operations, features, circuitry, logic, means, or instructions, or any combination thereof for performing a testing operation to determine whether each memory die of the plurality of memory dies is associated with an error based at least in part on bonding the plurality of memory dies to the redistribution layer.
Aspect 11: The method, apparatus, or non-transitory computer-readable medium of aspect 10, where the testing operation includes a burn-in operation.
Aspect 12: The method, apparatus, or non-transitory computer-readable medium of any of aspects 1 through 11, where each of the plurality of memory chips includes a volatile memory device.
Aspect 13: The method, apparatus, or non-transitory computer-readable medium of any of aspects 1 through 12, where each of the plurality of memory chips includes a dual in-line memory module (DIMM).
Aspect 14: The method, apparatus, or non-transitory computer-readable medium of any of aspects 1 through 13, where each of the plurality of memory chips includes one or more components associated with a power management integrated circuit (PMIC).
Aspect 15: The method, apparatus, or non-transitory computer-readable medium of any of aspects 1 through 14, where each of the plurality of memory chips includes one or more controllers.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 16: A memory device, including: a glass substrate; a redistribution layer on a first surface of the glass substrate, where the redistribution layer includes alternating layers of a first material and a second material, the layers of the second material including respective conductive paths; and one or more memory dies in electrical communication with the redistribution layer and coupled with the glass substrate via the respective conductive paths.
Aspect 17: The memory device of aspect 16, further including: a second redistribution layer on a second surface of the glass substrate, where the second redistribution layer includes alternating layers of the first material and the second material, the layers of the second material including respective conductive paths; and one or more second memory dies in electrical communication with the second redistribution layer and coupled with the glass substrate via the respective conductive paths.
Aspect 18: The memory device of any of aspects 16 through 17, further including: a protective covering around each of the one or more memory dies in electrical communication with the redistribution layer.
Aspect 19: The memory device of any of aspects 16 through 18, where the one or more memory dies are bonded with the redistribution layer using a flip-chip interconnect.
Aspect 20: The memory device of any of aspects 16 through 19, where the one or more memory dies are bonded with the redistribution layer using one or more bumps.
Aspect 21: The memory device of any of aspects 16 through 20, where the redistribution layer includes one or more through glass vias, the alternating layers of the first material and the second material are connected using the one or more through glass vias.
Aspect 22: The memory device of any of aspects 16 through 21, where the first material includes a polyimide material and the second material includes copper.
Aspect 23: The memory device of any of aspects 16 through 22, where the one or more memory dies include volatile memory.
Aspect 24: The memory device of any of aspects 16 through 23, where the one or more memory dies include a dual in-line memory module (DIMM).
Aspect 25: The memory device of any of aspects 16 through 24, further including: one or more components associated with a power management integrated circuit (PMIC).
Aspect 26: The memory device of any of aspects 16 through 25, further including: one or more controllers, where the one or more memory dies are coupled with the one or more controllers.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for manufacturing a memory module, comprising:
forming a redistribution layer on a first surface of a glass substrate, wherein the redistribution layer comprises alternating layers of a first material and a second material;
bonding a plurality of memory dies to the redistribution layer; and
singulating the plurality of memory dies together with the glass substrate to form the memory module.

2. The method of claim 1, further comprising:
prior to singulating, forming a second redistribution layer on a second surface of the glass substrate, wherein the second redistribution layer comprises alternating layers of the first material and the second material; and
bonding a second plurality of memory dies to the second redistribution layer,
wherein singulating the plurality of memory dies together with the glass substrate also includes the second plurality of memory dies.

3. The method of claim 2, wherein singulating the plurality of memory dies and singulating the second plurality of memory dies occur during a same manufacturing process.

4. The method of claim 1, wherein bonding the plurality of memory dies to the redistribution layer comprises:
bonding each of the plurality of memory dies to the redistribution layer using a flip-chip interconnect.

5. The method of claim 1, wherein bonding the plurality of memory dies to the redistribution layer comprises:
bonding each of the plurality of memory dies to the redistribution layer using a plurality of bumps.

6. The method of claim 1, further comprising:
forming a protective covering around each of the plurality of memory dies bonded to the redistribution layer.

7. The method of claim 1, wherein forming the redistribution layer comprises:
depositing the alternating layers of the first material and the second material; and
forming respective conductive paths at the layers of the second material, wherein one or more memory dies of a respective memory chip is coupled with the glass substrate via the respective conductive paths.

8. The method of claim 1, further comprising:
forming one or more through glass vias in the redistribution layer, wherein the alternating layers of the first material and the second material are connected using the one or more through glass vias.

9. The method of claim 1, wherein the first material comprises a polyimide material and the second material comprises copper.

10. The method of claim 1, further comprising:
performing a testing operation to determine whether each memory die of the plurality of memory dies is associated with an error based at least in part on bonding the plurality of memory dies to the redistribution layer.

11. The method of claim 10, wherein the testing operation comprises a burn-in operation.

12. The method of claim 1, wherein the memory module comprises a volatile memory device.

13. The method of claim 1, wherein the memory module comprises a dual in-line memory module (DIMM).

14. The method of claim 1, wherein the memory module comprises one or more components associated with a power management integrated circuit (PMIC).

15. The method of claim 1, wherein the memory module comprises one or more controllers.

16. A memory device, comprising:
a glass substrate;
a redistribution layer on a first surface of the glass substrate, wherein the redistribution layer comprises alternating layers of a first material and a second material, the layers of the second material including respective conductive paths; and
one or more memory dies in electrical communication with the redistribution layer and coupled with the glass substrate via the respective conductive paths.

17. The memory device of claim 16, further comprising:
a second redistribution layer on a second surface of the glass substrate, wherein the second redistribution layer comprises alternating layers of the first material and the second material, the layers of the second material including respective conductive paths; and
one or more second memory dies in electrical communication with the second redistribution layer and coupled with the glass substrate via the respective conductive paths.

18. The memory device of claim 16, further comprising:
a protective covering around each of the one or more memory dies in electrical communication with the redistribution layer.

19. The memory device of claim 16, wherein the one or more memory dies are bonded with the redistribution layer using a flip-chip interconnect.

20. The memory device of claim 16, wherein the one or more memory dies are bonded with the redistribution layer using one or more bumps.

21. The memory device of claim 16, wherein:
the redistribution layer comprises one or more through glass vias, and
the alternating layers of the first material and the second material are connected using the one or more through glass vias.

22. The memory device of claim 16, wherein the first material comprises a polyimide material and the second material comprises copper.

23. The memory device of claim 16, wherein the one or more memory dies comprise volatile memory.

24. The memory device of claim 16, wherein the one or more memory dies comprise a dual in-line memory module (DIMM).

25. A memory device, comprising:
a glass substrate formed by depositing a glass material;
a redistribution layer on a surface of the glass substrate, wherein the redistribution layer is formed by:
depositing alternating layers of a first material and a second material, the layers of the second material including respective conductive paths; and
one or more memory chips in electrical communication with the redistribution layer and coupled with the glass substrate via the respective conductive paths, formed by:
bonding a plurality of memory dies to a surface of the redistribution layer; and
singulating the plurality of memory dies to form the one or more memory chips, wherein each memory chip comprises one or more of the plurality of memory dies, and a respective glass substrate of the glass substrate and a respective redistribution layer of the redistribution layer.
